(19) United States
(12) Patent Application Publication
(10) Pub. No.: US 2001/0032388 A1
(43) Pub. Date: Oct. 25, 2001

(54) Structure and method for multiple diameter via

(76) Inventor: Terrel L. Morris, Garland, TX (US)

Correspondence Address: HEWLETT-PACKARD COMPANY, Intellectual Property Administration, P. O. Box 272400, Fort Collins, CO, 80527-2400, US

(21) Appl. No.: 09/885,851

(22) Filed: Jun. 20, 2001

Related U.S. Application Data
(62) Division of application No. 09/470,929, filed on Dec. 22, 1999.

(51) Int. Cl. H01K 3/10; B23B 39/00; H05K 3/02

(52) U.S. Cl. 29/852; 408/704; 29/846

(57) ABSTRACT

The present invention relates to the production of an improved via for attaching electrical connection pins to printed circuit boards. The inventive via provides a connection having robust mechanical attachment and minimal capacitance effects. The via provides a wide diameter for accepting an electrical connection pin and a reduced diameter along other portions of the length of the via for reduced capacitance and reduced electrical discontinuity.

### BACKGROUND

Generally, when establishing electrical contact across a junction of any form, it is desirable to have good impedance matching between the two (or more) points of electrical contact. For example, a 50 ohm transmission line is preferably connected to another 50 ohm transmission line with no discontinuities being introduced at the connection point itself. Where impedance discontinuities are present in an electrical connection, energy reflections may be generated which set up resonant conditions, thereby limiting the performance of a signal transmitted through the connection.

When making electrical connections on circuit boards, pins are generally mated with electrical contacts within the board. Generally, pins on chips, connectors, or other devices being attached to a circuit board are seated in holes which provide electrical continuity between the inserted pin and an appropriate electrical contact on the circuit board. A via is one mechanism for accomplishing such electrical connectivity between an inserted pin and a desired contact within a circuit board. Vias generally have associated electrical discontinuities from undesired capacitance which lowers the impedance at the point of connection, as discussed below. A number of approaches have been employed in the prior art to reduce the problem of undesired capacitance in vias, which approaches are discussed below. Herein, PCB refers to a printed circuit board.

FIG. 1 depicts a cross-section of a press-fit through-hole connector pin installed in a PCB via. Connector pin 101 protrudes through the via 102. A compliant section 103 of the connector pin 101 is firmly pressed against a portion 104 of the plated hole generally creating a tight fit.

A plurality of signal layers are shown in FIG. 1 in the form of horizontal lines on either side of connector pin 101. Signal layer 106 connects the via to other components within the PCB assembly. Since the insertion of the compliant section 103 of connector pin 101 is generally in tight frictional contact with area 104 during insertion, considerable downward force is exerted upon via 102. In order to protect against damage to the via 102 arising from the insertion force, anchor pads 105 are plated to the via 102 at each layer. The anchor pads 105 contribute a portion of the capacitance formed between the via 102 and the conducting layers of the PCB.

While the approach of FIG. 1 provides for a robust attachment of the pin 101 to via 102, it also generates substantial capacitance resulting in an electrical discontinuity at via 102. Effectively, a radial capacitor is created around each of the anchor pads. In view of this problem, other approaches have been pursued in an attempt to reduce the capacitance of the arrangement of FIG. 1.

FIG. 2 depicts a cross-section of a through-hole soldered connector pin installed in a PCB via. In this case, connector pin 201 protrudes through via 202. A solder joint traverses the length of the via 202, creating solder fillets 204 at the top and bottom of via 202. Signal layer 205 connects via 202 to other selected components within a PCB assembly. Although anchor pads as employed in press-fit applications described in connection with FIG. 1 are not required in the arrangement of FIG. 2, the via 202 diameter is sufficient to form a significant capacitor between the via 202 and surrounding conducting plates 203. Although capacitance stemming from anchor pads is avoided with this design, the presence of a substantial via 202 diameter and proximate conducting plates 203 generate substantial undesired capacitance.

One technique employed to reduce the capacitance associated with large through-hole vias (vias which extend entirely through a circuit board) is redesigning the component to incorporate one of the standard surface mount attachment methods, including J-lead, gull-wing leads, Ball Grid Array (BGA), Land Grid Array (LGA), and solder column attachment. Advantages of surface mounting include establishing reduced via diameter and associated capacitance, as well as a single process for soldering all components to the circuit board. The disadvantages associated with the above approaches include increased redesign costs and tooling costs. Furthermore, certain pad patterns are not easily converted to a standard Surface Mount technology (SMT) format. SMT mounted joints are generally less able to withstand shear forces than through-hole joints, and shear forces are a substantial issue in some designs, such as 90 degree connector designs. One design incorporating the surface mount attachment method is discussed in connection with FIG. 3.

FIG. 3 is a cross-sectional view of a typical through-hole surface mount. A surface mount lead 302 is connected to a reduced diameter via 301 by solder fillets 303 and 304. The via 301 ultimately establishes electrical contact with signal layer 305. A benefit of this design is that the reduced diameter of via 301 in comparison with the vias of FIGS. 1 and 2 reduces the capacitance of via 301 thereby reducing the electrical discontinuity in the electrical connection made across via 301. However, a disadvantage of this design is that the surface mount soldered connection is generally less robust than the connector-via connections depicted in FIGS. 1 and 2. Moreover, a larger surface area is needed to make the connection.

FIG. 4 shows a cross sectional view 400 of a typical blind via surface mount connection. A “blind” via refers to a via which does not extend entirely through a circuit board assembly. The smaller via 401 does not protrude through the board, and thus generates less capacitance in the electrical connection made across via 401 because of a reduced diameter and a reduced length. The via 401 is connected to SMT lead 402 by a solder connection having solder fillets at 403 and 404. Electrical continuity is established at layer 405. Although the arrangement of FIG. 4 provides for reduced via capacitance, blind vias are typically a more expensive board technology and are not appropriate for many applications. Furthermore, the surface mount arrangement of FIG. 4, as with that of FIG. 3, is more sensitive to shear stresses than are through-hole connector arrangements.

A second approach to mitigating the effect of vias is to adapt a standard through-hole lead by cutting the leads on a part to be connected flush to an interface of a circuit board, and to then attach the part using SMT. FIG. 5 shows a typical press-fit connector prior to a pin cutting operation. FIG. 6 shows the same connector after the pin cutting operation. This attachment configuration is commonly referred to as a “butt joint” connection since the flat cut end of the pin abuts the surface mount pad. Advantages of this approach include reduced via capacitance and increased PCB connection path density attained by using smaller through-hole vias or blind vias in place of large through-hole pins and vias.

However, the butt joint approach also presents disadvantages. A first disadvantage of this approach is that the solder joint formed by this type of connection is inherently weaker than that formed employing the standard SMT methods. This is due to the fact that the butt joint has less surface area in contact with the PCB, thereby generating a solder joint with less solder fillet area and less wetted area. A “wetted area” is the area which is coated with molten solder during the reflow operation. The wetted area generally includes the pin and hole, or alternatively, the pin and pad. If a shear force is applied to a solder joint with reduced area, high point loads are generated, thereby increasing the opportunity for solder joint stress failure.

Cutting the leads on a part generally requires a machining operation which yields cut leads of uniform length. Variation in length of the pins results in gaps between the shorter pins and the SMT pads. Gaps between the pins and pads further reduce the strength of the solder joints, and in extreme cases, may prevent solder joints from forming during the solder reflow process. FIG. 10 illustrates this problem and is described in more detail below.

One approach to cutting the pins has been to lap the pin array. This creates an expensive secondary manufacturing step. If the lapping is done on plated pins, which is usually the case, then base metals may be exposed during the lapping operation. These exposed areas must then be post-plated or solder dipped, adding further steps and expense.

FIG. 7 shows a cross-sectional view of a connector pin which has been cut and soldered to a small through-hole via. When compared to the pin and via in FIG. 1, it can be seen that the via 702 can be made substantially smaller (down to 50% or even 25% of the original size), and that the press-fit anchor pads are not required.

FIG. 7 depicts a design involving an SMT joint which allows a calibrated amount of solder paste to reflow and “wick” down the via 702. This additional solder volume is made up by allowing a larger amount of solder paste to be applied during the previous manufacturing step. In FIG. 7, the pin 701 is soldered to the pad, thereby forming solder fillet 703. The signal layer 704 is connected to the via 702 to provide signal connectivity. Generally, solder is “wicked” into the via to level 705. Wicking is the capillary action of liquid solder in a tube formed by a via. Generally, features enabling wicking to occur include a solder flow geometry suitable for capillary action and the provision of a continuous solder wetting surface. The via may include an inward curve in the center of the via which is known as a “dog bone”. This is caused by plating very small diameter holes in thick boards. In extreme cases, the hole may be plated shut.

FIG. 8 shows a connector pin which has been cut and soldered to a point offset from a small through-hole via. Pin 801 is soldered to the pad 802, forming solder fillet 803. Signal layer 804 connects the via to other components on the circuit board. The offset pad arrangement presents the advantage of not requiring that solder be allowed to “wick” down the via. However, a significant disadvantage is that the pad takes up more surface area, adding capacitance and reducing overall connector density.

FIG. 9 shows a cross-sectional view of a connector pin which has been cut and soldered to a small offset blind via. Pin 901 is soldered to pad 902, forming solder fillet 903. The pad 902 is connected to blind via 904, which attaches to signal layer 905.

FIG. 10 depicts a connection of a field of three pins of unequal length soldered to pads on a circuit board. The connection depicted in FIG. 10 illustrates the problem in a standard butt-joint arrangement when one pin in a field of pins is shorter than the surrounding pins. Pins 1001 and 1002 have been cut to the correct length, and properly contact pads 1003 and 1004, forming solder joints 1005 and 1006. Pin 1007 is several mils shorter than the neighboring pins 1001 and 1002, and does not properly contact pad 1008. As a result, the solder 1009 solidifies in a manner which does not provide a reliable connection. Note that this example shows only one of many possible defective solder patterns which can occur as a result of poor pin-to-pad contact.

FIG. 15 depicts a via employed in the prior art for microwave radio frequency applications. In the microwave RF industry, it has been determined that vias disrupt communications, particularly at higher frequencies. Generally, the upper portion of the via is of primary interest for this application. Element 1502 is shown pointing to the pad near the upper portion of the via.

The area of interest 1501 is shown bounded by a dashed line. Generally, the portion bounded by the dashed line provides no operational benefit while still adding undesired capacitance. In the prior art, the area inside the dashed line is generally removed by a process of counter-boring. This approach presents several problems. A second drilling operation is generally required which usually requires the time-consuming step of registering the position of the circuit board a second time. The material drilled out by the counter-boring operation may clog the hole through the circuit board, thereby requiring a cleaning operation. Further, at the conclusion of the counter-boring operation, bare copper is generally exposed in the counter-bored region, because protective material covering the copper is removed during the counter-boring operation. The presence of exposed copper generates a long term reliability problem because of the reactive nature of copper.

Generally, if a press-fit operation were employed for insertion of a pin connector, a long pin would be employed with an associated undesired capacitance. Generally, a through-hole soldering operation would not be feasible with this embodiment. Further, capillary action for solder placed in the via would generally not be available because much of the required wetting surface necessary for capillary fluid flow would have been removed by the counter-boring operation and because the geometry of the counter-bored region is not conducive to capillary action. Moreover, the counter-boring operation described above generally weakens the board structure. Accordingly, significant mechanical stresses on the board must be avoided, thereby limiting the choice of available assembly operations.

Therefore, there is a need in the art for a pin connection mechanism which provides for minimal capacitance and provides a robust mechanical attachment of a connector to a printed circuit board.

There is a further need in the art for a mechanism which provides a mechanically robust connection with minimal capacitance and a minimum of workpiece handling.

There is a still further need in the art for a mechanism which provides a mechanically robust connection with minimal capacitance while still allowing for through-hole soldering employing capillary action.

There is a still further need in the art for a mechanism which provides a mechanically robust connection with minimal capacitance while preventing bare copper or other reactive conductive material from being exposed after manufacturing is complete, thereby providing long term durability for the conductive material.

### SUMMARY OF THE INVENTION

These and other objects, features and technical advantages are achieved by a system and method which provides a via having a diameter which is variable along its length, having sufficient width at an attachment point of a connector to accept a connector pin, and narrow enough along most of the via length to reduce the capacitance between the via and surrounding materials within a printed circuit board. The inventive approach thereby preferably provides both a secure connection between the via and a connector and reduced electrical discontinuity at the via.

In a preferred embodiment, a pin of relatively simple geometry, such as that resulting from a rough shearing of a variety of types of pre-existing pins, may be affixed with solder to the via where the diameter of the via is of appropriate diameter to permit attachment of the pin. The ability to use a pin of simple geometry preferably enables use of a sheared pin using a pre-existing press-fit design. Preferably, the pin is inserted some distance into the via which permits secure and robust positioning of the pin. The via diameter at the insertion point of the connector pin may be established so as to enable relatively force free insertion of the connector pin.

In a preferred embodiment, solder may be pre-loaded into the via, the connector pin then inserted, and a solder re-flow process employed to finally secure the pin in place. This approach removes the need for capillary action to pull the solder up from the opposite side of the printed circuit board from the point of pin insertion. The inventive mechanism thereby preferably provides a mechanically and electrically robust connection.

In a preferred embodiment, a via having two or more diameters may be produced while the via remains at a single work station. This approach avoids the time consuming and expensive process of having to position, or register, a via separately for separate machining operations. Preferably, a workpiece is registered with a drill machine. Afterward, the same drill machine is preferably employed to successively drill out sections of the circuit board having different diameters and different depths to provide a variable diameter via. Where sections of different diameters and different depths are drilled, the drilling operations may generally be performed in any order.

It is an advantage of a preferred embodiment of the present invention that it provides an electrical connection which is mechanically robust and generates minimal electrical discontinuity.

It is a further advantage of a preferred embodiment of the present invention that solder may be inserted from the same side of the circuit board as the connector pin, thereby avoiding the use of capillary action to draw in solder.

It is a still further advantage of a preferred embodiment of the present invention that a variable diameter via may be produced at a single machine requiring only one workpiece registration operation.

It is a still further advantage of a preferred embodiment of the present invention that the required insertion force for the pin connector is minimal, thereby avoiding excessive stress on the circuit board assembly.

The foregoing has outlined rather broadly the features and technical advantages of the present invention in order that the detailed description of the invention that follows may be better understood. Additional features and advantages of the invention will be described hereinafter which form the subject of the claims of the invention. It should be appreciated by those skilled in the art that the conception and specific embodiment disclosed may be readily utilized as a basis for modifying or designing other structures for carrying out the same purposes of the present invention. It should also be realized by those skilled in the art that such equivalent constructions do not depart from the spirit and scope of the invention as set forth in the appended claims.

### BRIEF DESCRIPTION OF THE DRAWING

For a more complete understanding of the present invention, and the advantages thereof, reference is now made to the following descriptions taken in conjunction with the accompanying drawing, in which:

FIG. 1 depicts a cross-section of a press-fit through-hole connector pin installed in a PCB via;

FIG. 2 depicts a cross-section of a through-hole soldered connector pin installed in a PCB via;

FIG. 3 is a cross-sectional view of a typical through-hole surface mount;

FIG. 4 shows a cross sectional view of a typical blind via surface mount connection;

FIG. 5 shows a typical press-fit connector prior to a pin cutting operation;

FIG. 6 shows a typical press-fit connector after a pin cutting operation;

FIG. 7 shows a cross-sectional view of a connector pin which has been cut and soldered to a small through-hole via;

FIG. 8 shows a connector pin which has been cut and soldered to a point offset from a small through-hole via;

FIG. 9 shows a cross-sectional view of a connector pin which has been cut and soldered to a small offset blind via;

FIG. 10 depicts a connection of a field of three pins of unequal length soldered to pads on a circuit board;

FIG. 11 depicts a via having a variable diameter according to a preferred embodiment of the present invention;

FIG. 12 depicts a variable diameter blind via according to a preferred embodiment of the present invention;

FIG. 13 depicts a field of three connecting pins connected with solder to vias in a circuit board according to a preferred embodiment of the present invention;

FIG. 14A depicts a drilling operation which establishes a narrow diameter of a via according to a preferred embodiment of the present invention;

FIG. 14B depicts a drilling operation which establishes a wide diameter for an upper portion of a via according to a preferred embodiment of the present invention;

FIG. 14C depicts a mechanism for implementing a multiple diameter via in a single step according to a preferred embodiment of the present invention; and

FIG. 15 depicts a via employed in the prior art for microwave radio frequency applications.

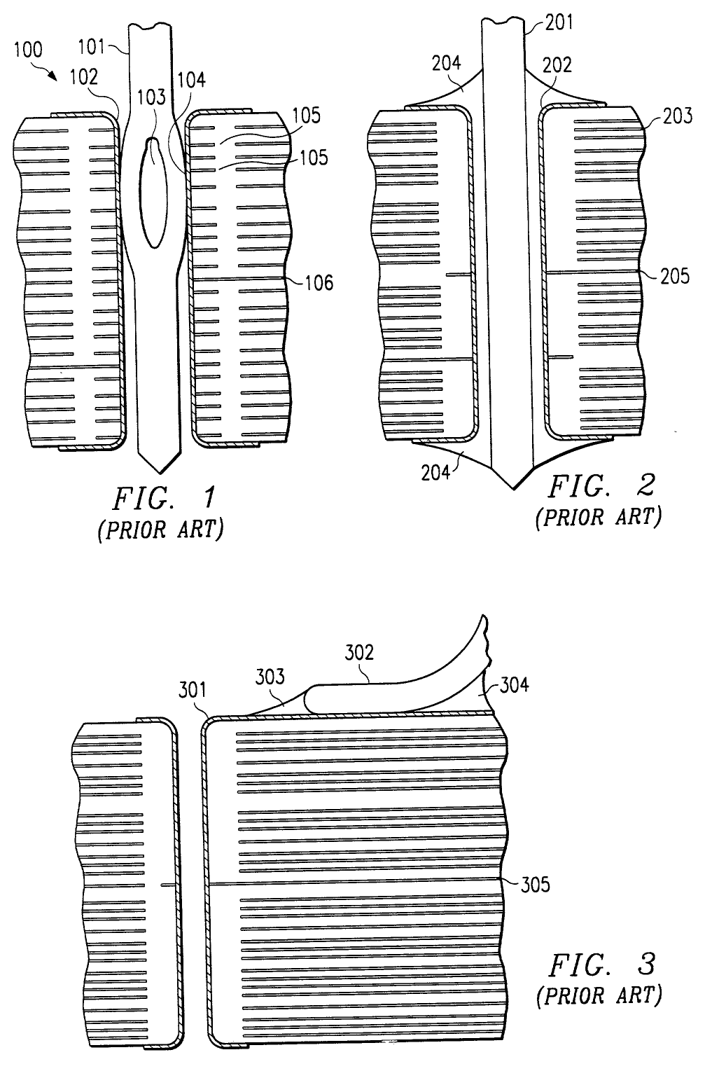

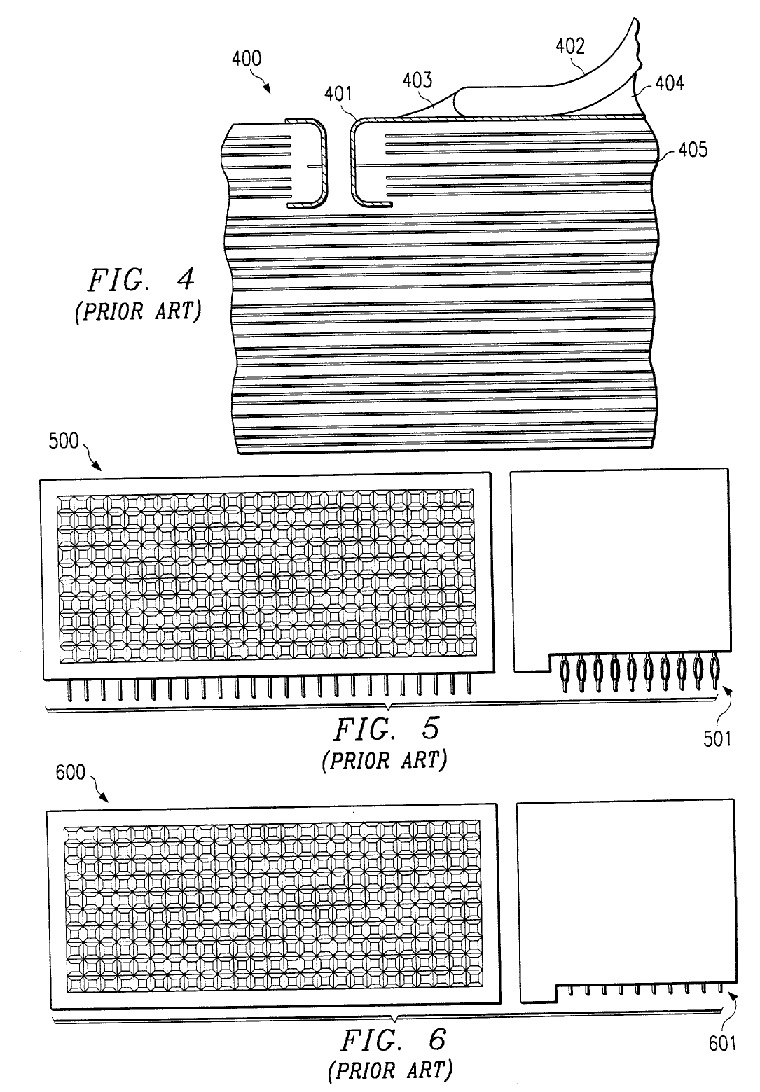

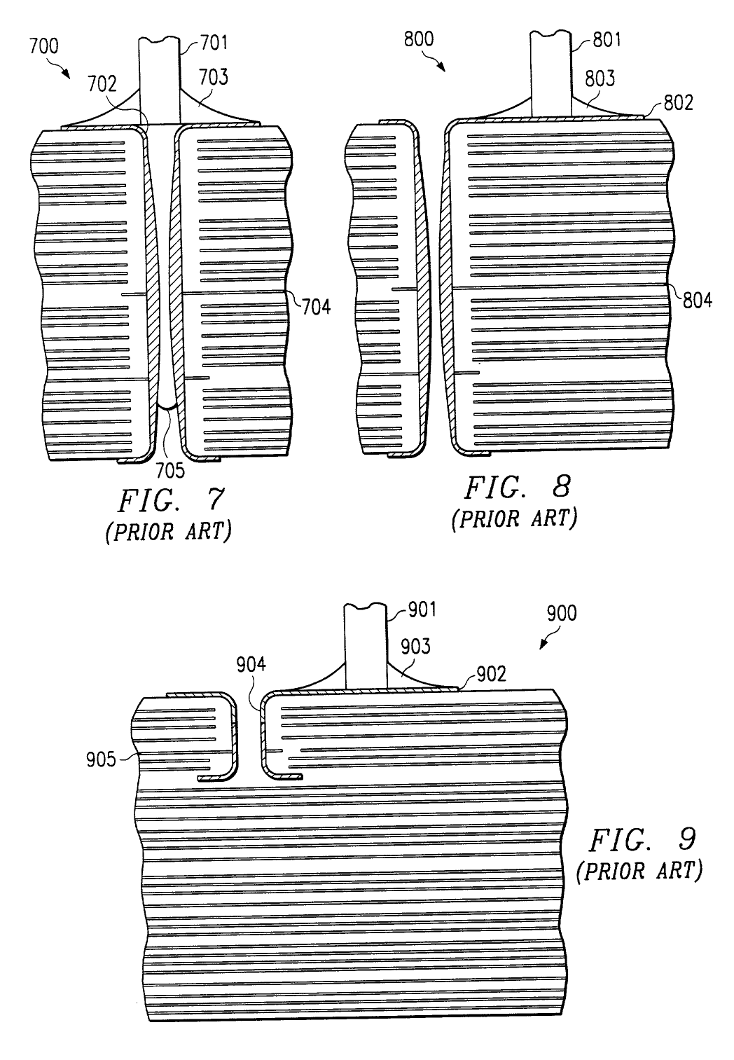

### DETAILED DESCRIPTION

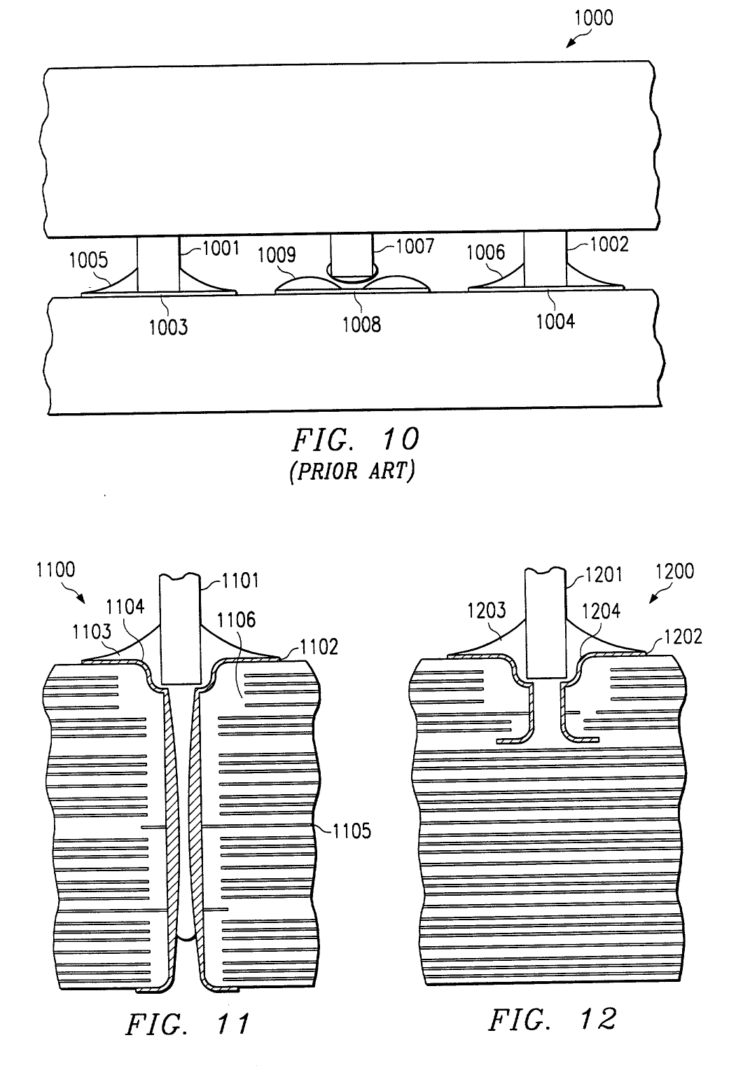

FIG. 11 depicts a via having a variable diameter according to a preferred embodiment of the present invention. The pin 1101 is attached to the pad 1102 forming the solder joint 1103. Curvature 1104 of the pad 1102 allows a “cup” or “well” to be formed, which in turn provides additional solder joint area. A further benefit is that this “well” can be filled with additional solder paste, allowing good solderability even with the solder “wicking” associated with a through-hole via.

In a preferred embodiment, the via includes two basic diameters along its length. A first diameter is wide enough to accommodate insertion of the pin 1101 and an appropriate quantity of solder, thereby providing a mechanically robust connection. An exemplary diameter for acceptance of pin 1101 would be between 20 to 40 mils depending upon the size of the pin 1101. For this same range of pin sizes, an exemplary diameter for the narrower section of the via below the pin attachment region would be between 6 to 14 mils. The reduced diameter of this lower portion of the via preferably operates to reduce the capacitance of the via. It will be appreciated that a wide range of diameters could be employed for the upper and lower portions of the via, and all such variations are included within the scope of the invention.

In a preferred embodiment, a hole in the circuit board is formed by performing a sequence of boring or drilling operations on the circuit board to remove material therefrom, thereby forming a hole having a plurality of sections having different diameters. The final via is preferably formed by plating the inner surface of this multiple section hole in the circuit board material. The plating process adds material to the hole and thereby generally changes the internal dimensions of the hole to form the via. Accordingly, a distinction is preferably made between a “bore diameter” and a “plating diameter” associated with each section of a via. The bore diameter of a section of the via is the diameter of the circuit board material in that section arising from the boring or drilling operation on the circuit board material which preceded the plating process. The bore diameter established by the boring process generally remains unchanged after plating material is added. The plating diameter of a section of the via is the diameter formed by the plating material which is attached to the circuit board material at that point. Within any given section of the via, the bore diameter will generally exceed the plating diameter by a distance equal to the combined thicknesses of the plating material on either side of the plating diameter.

The provision of a wide upper via portion preferably enables pin 1101 a pin connector to be partially inserted into the upper portion and space for creation of an effective solder joint to affix the pin 1101 to the via, thereby providing a robust mechanical attachment of the pin 1101 to the via. A narrow lower portion of the via preferably operates to minimize the capacitative effect on the electrical connection made across the via.

In a preferred embodiment, conductive layers in the circuit board 1106 near the wide portion of the via are kept a safe distance, or set back, from the via to avoid interference with the drilling operation which produces the wider diameter. This “set back” placement of the conductive layers 1106 is preferably continued for a safe distance beyond the end of the end of the wide portion of the via. The “set back” position is continued for this “safe distance” because of registration tolerances of the circuit board manufacturing process.

Generally, the deeper the wide portion of the via extends into the circuit board, the more robust the mechanical attachment of the pin 1101. Another benefit of a greater depth of the wide portion is that greater tolerance of pin length variation, and/or pin connector placement may be achieved. This matter is discussed in greater detail in connection with FIG. 13.

However, the goal of via capacitance reduction is generally enhanced by minimizing the length of the depth of the wide portion of the via. There is therefore generally a tension between optimizing the characteristics of mechanical attachment robustness and pin length variation tolerance and the objective of lowering capacitance of the via. In an exemplary embodiment, a wide diameter depth of 10 to 20 mils has been found to appropriately balance the competing objectives. It will be appreciated that a wide range of depths both lower than 10 mils and higher than 20 mils may also be employed, and that all such variations are within the scope of the present invention.

Although the case of two distinct diameters for the via has been discussed above, it will be appreciated that the inventive vias may include any number of diameters. Moreover, the via may be shaped such that the via has a continuously variable diameter.

FIG. 12 depicts a variable diameter blind via according to a preferred embodiment of the present invention. The pin 1201 is attached to the pad 1202 forming the solder joint 1203. Curvature 1204 of pad 1202 allows a cup or well to be formed in similar manner to the case of FIG. 11, which in turn provides a larger and more robust solder joint than a standard SMT butt joint, while providing the electrical benefits of a smaller via. In this case, the use of a blind via operates to further reduce the capacitance contribution of the via by reducing the length of the via.

FIG. 13 depicts a field of three connecting pins connected with solder to vias in a circuit board according to a preferred embodiment of the present invention. The FIGURE demonstrates the ability of the inventive via to tolerate variation in the length and relative placement with respect to the via of connecting pins 1301, 1302, and 1309. Pins 1301 and 1302 are of normal length and attach to pads 1303 and 1304, respectively, forming normal solder fillets 1305 and 1306. Curved via portions 1307 and 1308 provide a “cup” for solder allowing a more robust solder joint. Pin 1309 has been cut too short, and therefore terminates at a position further from the circuit board than do pins 1301 and 1302. Because of the depth of the well indicated by curve 1312, pin 1309 may still make solder contact with pad 1310, thereby making slightly reduced but still adequate contact with solder fillet 1311.

Curved via portion 1307 preferably allows enough solder volume and extra depth to allow pin 1309 to be effectively soldered to pad 1310. The electrically and mechanically robust solder contact made with between the circuit board and pin 1309 contrasts sharply with the prior art case of pin 1007 in FIG. 10, which was too short to make proper contact with the circuit board.

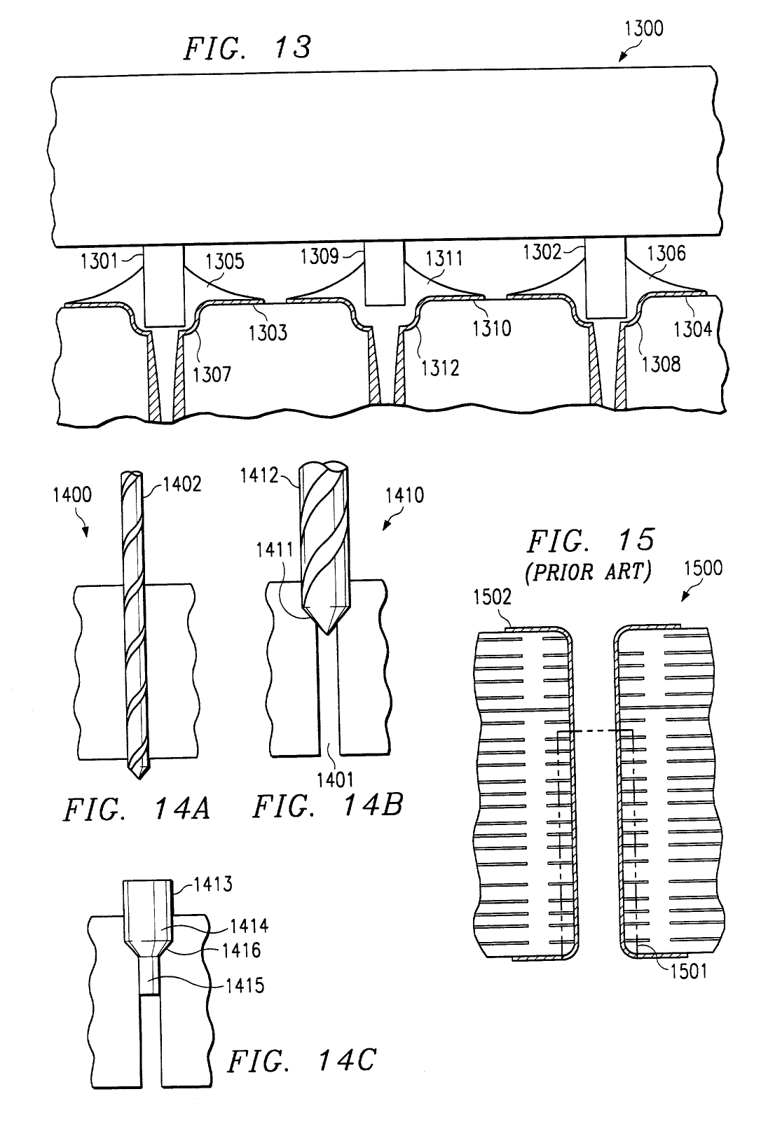

FIG. 14A depicts a drilling operation which establishes a narrow diameter of a via according to a preferred embodiment of the present invention. FIG. 14B depicts a drilling operation which establishes a wide diameter section for an upper portion of a via according to a preferred embodiment of the present invention. It will be appreciated that the wide and narrow sections may be drilled in any order. Moreover, the invention is not limited to drilling only two sections.

In an alternative embodiment, three or more sections may be drilled with each section having a unique diameter and depth among the sections bored or drilled. As with the two section case, the three or more sections need not be drilled in an order dictated by the magnitude of their diameters or depths but may be drilled in any order, and all such variations are included in the scope of the invention.

In a preferred embodiment, a modified standard drill operation is employed to create a well shaped opening at the top of the via to enable a connector to be readily attached to the via. FIG. 14A shows the standard drill process for a small via 1401 using the small drill bit 1402. FIG. 14B depicts a drill process for creating the controlled-depth drill of the cup 1411 by the larger drill bit 1412. The wider drilling operation preferably takes advantage of the taper of drill bit 1412 to form a graduated change in the diameter of the via between the diameter of the small drill bit and the diameter of the larger drill bit 1412 at its widest point. The resulting via is then plated using standard plating practices.

In general, accurate registration of a part in a machine for a drilling or other machining operation represents a significant portion of the time required to complete the contemplated machining operation. For the operations depicted in FIGS. 14A and 14B, the workpiece, in this case a circuit board, need only be registered once at a single drilling machine. Subsequently, two consecutive drilling operations employing drill bits of different diameters are preferably used on the part without requiring replacement and re-registration of the part. This arrangement provides considerable advantage in process time over procedures requiring reworking the circuit board on a separate machine. After the drilling operations are complete, the exposed surface of the hole, or via, is preferably plated. Preferably, the entire cup shaped upper area of the via is plated, thereby preventing any base metals from being exposed and providing protection and durability for the circuit board materials. The above described drilling operation is preferably employed for pin connector attachments to a via. However, the process may also be employed with surface mount devices, such as pin grid arrays (PGAs).

Preferably, the drilling operations occur in direct sequence, thereby enabling the workpiece to remain in place in between the first and second drilling operations and avoiding the time and effort associated with accurately registering the workpiece with a second drilling machine. Alternatively however, different machines may be employed to drill a plurality of holes in the circuit board. Also, other operations may be performed in between drilling operations. Generally, automatic PCB drilling equipment permits drill bits to be changed without removing the PCB panel from the drilling equipment, so preferably, any required modification of the process for manufacturing the PCB panel should be small.

In a preferred embodiment, the plurality of drilled sections are concentric as indicated in FIG. 14B, thereby providing for easier drilling operations and producing a via with geometric features which are symmetric in all directions. In an alternative embodiment however, the sections which combine to form the hole for the via need not necessarily be aligned, but may be offset from one another.

FIG. 14C depicts a mechanism for implementing a multiple diameter via in a single step according to an alternative embodiment of the present invention. Instead of producing multiple diameter vias by conducting a sequence of drilling operations employing drill bits of different diameters, a single drill bit having multiple diameters could be employed to produce the desired via in a single drilling step. Preferably, the use of a multiple diameter drill bit would conserve processing time by requiring just one drilling operation. For example, in comparison with a drilling operation involving two drill bits, the time required for dropping off the first bit, attaching a second bit, and performing the second drilling operation would be avoided in the case of deployment of a two diameter drill bit.

Generally, optimal feed rates and drilling speeds for a drilling operation vary with a number of factors including the material being drilled and the diameter of the drill bit currently in operation. When using a multiple diameter drill bit therefore, the feed rate and drilling speed would therefore preferably be separately adjusted as each stage or diameter of the drill bit makes contact with the surface of the material being drilled. In this manner, optimal drilling results may preferably be obtained throughout a drilling operation employing a multiple diameter drill bit.

When drilling a PCB with a multiple diameter drill bit, in order to ensure that each diameter in the PCB is drilled to the right depth, the location of each stage of the drill bit relative to each other stage on the drill bit is preferably accurately established and preserved. Accordingly, when sharpening the multiple stage drill bit, material should be removed from each stage of the bit so as to preserve the location of each stage of the bit relative to each other stage, thereby ensuring that the geometry of holes drilled after a sharpening operation is the same as for those drilled before the sharpening operation.

In a preferred embodiment, drill bit 1413 is a two-diameter or two stage drill bit. A first stage 1415 of bit 1413 is narrow and generally long enough to produce a through-hole in the circuit board when the drilling operation is brought to an appropriate depth. The diameter of the first stage 1415 of bit 1413 is such as to produce a portion of a via which has minimal capacitance. Preferably, a second stage 1414 of the bit 1413 has a larger diameter than the first stage. The diameter of the second stage 1414 is preferably suitable for creating a well or opening at the top of the via to provide for easy attachment of a connector to the via and for easy loading of solder into the top portion of the via. Preferably, the slope or grade 1416 of the transition region between the first stage 1415 and the second stage 1414 is selected so as to create a desired shape for the base of the well or upper portion of the via. It is noted that a range of slopes or grades may be selected, and all such variations are within the scope of the present invention.

In an alternative embodiment, the length of the first stage 1415 of drill bit 1413 may be selected so as to create a blind via in a circuit board. Where the thickness of a circuit board to be drilled is known, the vertical motion of the drilling machine during the drilling operation and the length of the first stage of the drill bit may be selected so as to create blind vias with a range of different depths as measured with respect to the top surface of the circuit board.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. Structure for providing a connection in a circuit board comprising:
a via having a plurality of diameters;
a first section of the via having a first bore diameter; and
a second section of said via, below said first section, having a second bore diameter smaller than said first bore diameter, wherein substantially all of a surface area of said via is plated, thereby forming a plating surface of said via.

2. The structure of claim 1, wherein the first bore diameter is larger than a diameter of a pin connector and the second bore diameter is smaller than the diameter of the pin connector.

3. The structure of claim 1, wherein the via terminates at a point within said circuit board, thereby forming a blind via.

4. The structure of claim 1, wherein a curvature in the plating surface of said via between said first section of said via and said second section of said via provides a solder container.

5. The structure of claim 1, further comprising:
a pin connector partially inserted into said first section; and
a solder connection between said pin connector and the plating surface of the first section of the via.

6. The structure of claim 5, wherein a depth of said first section of said via exceeds a variation in position of an end of said pin connector partially inserted into said first section, thereby enabling effective electrical contact between said via and said pin connector which is tolerant of pin connector end position variation.

7. The structure of claim 1, wherein attachment of a connector to said via comprises a surface mount connection.

8. The structure of claim 1, wherein the via extends entirely through said circuit board, thereby forming a through-hole via.

9. The structure of claim 1, wherein said first section and said second section are concentric.

10. The structure of claim 1, wherein said first section and said second section are non-concentric.

11. A via produced according to a process comprising the steps of:
producing a hole in a circuit board having a plurality of sections, wherein each section has a different diameter; and
plating a surface of said hole, thereby establishing said via with a plating surface, wherein the step of plating succeeds said step of producing.

12. The via of claim 11, wherein the step of producing comprises:
performing a single drilling operation employing a multiple diameter drill bit.

13. The via of claim 11, wherein the step of producing comprises:
performing a plurality of concentric drilling operations, wherein each drilling operation employs a different single-diameter drill bit.

14. The via of claim 13, wherein the step of producing comprises the further step of:
preserving a positioning accuracy of said circuit board with respect to said machining station during said plurality of drilling operations and during periods between successive drilling operations of said plurality of drilling operations.

15. The via of claim 11, wherein the step of producing comprises:
performing a plurality of drilling operations, wherein at least two drilling operations of said plurality of drilling operations are not concentric.

16. A method for producing a via, the method comprising the steps of:
producing a hole in a circuit board having a plurality of sections, wherein each section has a unique diameter; and
plating a surface of said hole, thereby establishing said via with a plating surface, wherein said step of plating succeeds said step of producing.

17. The method of claim 16, wherein the step of producing comprises the steps of:
performing a plurality of concentric drilling operations, wherein:
each drilling operation employs a drill bit having a different diameter and drills to a particular depth; and
the plurality of concentric drilling operations may be performed in any order.

18. The method of claim 16, wherein the step of producing comprises the steps of:
a. drilling a first section having a first diameter to a first depth employing a first drill bit; and
b. drilling a second section having a second diameter to a second depth greater than said first depth employing a second drill bit narrower than said first drill bit, wherein step a and step b may be performed in any order.

19. The method of claim 18, wherein the step of producing further comprises the step of:
preserving a positioning accuracy of said circuit board at said machining station during steps a and b and in between steps a and b.

20. The method of claim 16, wherein the plating surface provides a solder cup.
